(19) United States
(12) Patent Application Publication
(10) Pub. No.: US 2026/0280506 A1
(43) Pub. Date: Sep. 17, 2026

(54) DAMPING RESONANCE ELEMENT WITH DOUBLE-SIDED DC FEEDING TECHNIQUE FOR DC TO MM-WAVE HIGH GAIN CASCODE SINGLE-ENDED/DIFFERENTIAL DISTRIBUTED AMPLIFIER

(71) Applicant: CIENA CORPORATION, Hanover, MD (US)

(72) Inventors: Aref Pourzadi, Ottawa (CA); Jeffrey Henry Bennett, Ottawa (CA)

(73) Assignee: CIENA CORPORATION, Hanover, MD (US)

(21) Appl. No.: 19/081,486

(22) Filed: Mar. 17, 2025

(51) Int. Cl. H03F 3/60; H03F 1/22; H03F 1/30; H03F 3/45

(52) U.S. Cl. CPC H03F 3/605; H03F 1/22; H03F 1/302; H03F 3/45085; H03F 2200/255; H03F 2200/423; H03F 2200/451

(57) ABSTRACT

Aspects of the subject disclosure may include, for example, a plurality of amplification stages arranged to receive a radio frequency (RF) input signal and provide an amplified output signal, a double-sided DC feeding system configured to supply DC bias voltages to the plurality of amplification stages from both ends of the amplifier circuit, thereby reducing current-resistance (iR) voltage drops in a DC bias line and ensuring uniform biasing across all amplification stages, an input transmission line interconnecting the plurality of amplification stages, the input transmission line configured to distribute the RF input signal from an input of the amplifier circuit to each respective amplification stage of the plurality of amplification stages, and an output transmission line interconnecting the plurality of amplification stages, the output transmission line configured to combine respective output signals of the respective amplification stages and provide the amplified output signal at an output of the amplifier circuit. Other embodiments are disclosed.

### FIELD OF THE DISCLOSURE

The subject disclosure relates to techniques for design and operation of improved amplifier circuits.

### BACKGROUND

High performance amplifier circuits have a large number of applications in environments from DC-to-millimeter-wave. One such application includes driving optical signals of high performance optical modulator circuits. Such amplifier circuits should be able to provide a full range output voltage across the full operating range.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of an optical transmission unit in accordance with various aspects described herein.

FIG. 2 is a block diagram illustrating an exemplary, non-limiting embodiment of an amplifier in accordance with various aspects described herein.

FIG. 3 is a block diagram illustrating a conventional single-ended N-stage distributed amplifier circuit.

FIG. 4 is a block diagram illustrating a conventional differential N-stage distributed amplifier circuit.

FIG. 5 is a block diagram illustrating an exemplary, non-limiting embodiment of a single-ended N-stage distributed amplifier circuit in accordance with various aspects described herein.

FIG. 6 is a block diagram illustrating an exemplary, non-limiting embodiment of a differential N-stage distributed amplifier circuit in accordance with various aspects described herein.

FIG. 7 depicts an illustrative embodiment of a method in accordance with various aspects described herein.

### DETAILED DESCRIPTION

The subject disclosure describes, among other things, illustrative embodiments for a high-frequency distributed amplifier circuit featuring a double-sided DC feeding system to ensure uniform biasing and reduce iR voltage drops across multiple cascode-configured amplification stages. This may achieve superior high-frequency performance and integrates transmission lines to minimize parasitic effects, enhancing gain and bandwidth. The amplifier is particularly suited for driving optical modulators, offering differential drive capability and stable operation at frequencies exceeding 100 GHz. Other embodiments are described in the subject disclosure.

One or more aspects of the subject disclosure include a plurality of amplification stages arranged to receive a radio frequency (RF) input signal and provide an amplified output signal, a double-sided DC feeding system configured to supply DC bias voltages to the plurality of amplification stages from both ends of the amplifier circuit, thereby reducing current-resistance (iR) voltage drops in a DC bias line and ensuring uniform biasing across all amplification stages, an input transmission line interconnecting the plurality of amplification stages, the input transmission line configured to distribute the RF input signal from an input of the amplifier circuit to each respective amplification stage of the plurality of amplification stages, and an output transmission line interconnecting the plurality of amplification stages, the output transmission line configured to combine respective output signals of the respective amplification stages and provide the amplified output signal at an output of the amplifier circuit.

One or more aspects of the subject disclosure include a plurality of amplification stages arranged in an amplifier structure having a first end and a second end, an amplification stage of the plurality of amplification stages comprising a plurality of transistors arranged in a cascode arrangement to amplify a radio frequency (RF) input signal and produce an amplified output signal, a double-sided DC feeding system configured to supply DC bias voltages to the plurality of amplification stages from the first end of the amplifier structure and from the second end of the amplifier structure of the distributed differential amplifier, thereby reducing current-resistance (iR) voltage drops in a DC bias line and ensuring uniform biasing across all stages, an input transmission line interconnecting the plurality of amplification stages, the input transmission line configured to distribute the RF input signal from an input of the distributed differential amplifier to each respective amplification stage of the plurality of amplification stages, a first input biasing circuit physically coupled to the input transmission line at the first end of the amplifier structure to provide a first input DC biasing voltage to the input transmission line, and a second input biasing circuit physically coupled to the input transmission line at the second end of the amplifier structure to provide a second input DC biasing voltage to the input transmission line.

One or more aspects of the subject disclosure include a plurality of amplification stages, each amplification stage of the plurality of amplification stages configured in a cascode arrangement to receive a radio frequency (RF) input radio frequency signal and provide an output signal, an input transmission line interconnecting the plurality of amplification stages, the input transmission line configured to distribute the RF input signal from an input of the distributed amplifier circuit to each respective amplification stage of the plurality of amplification stages, and a double-sided DC feeding system configured to supply DC bias voltages to the plurality of amplification stages from a first end of the distributed amplifier circuit and a second end of the distributed amplifier circuit, thereby reducing current-resistance (iR) voltage drops in a DC bias line and ensuring uniform biasing across all amplification stages of the plurality of amplification stages.

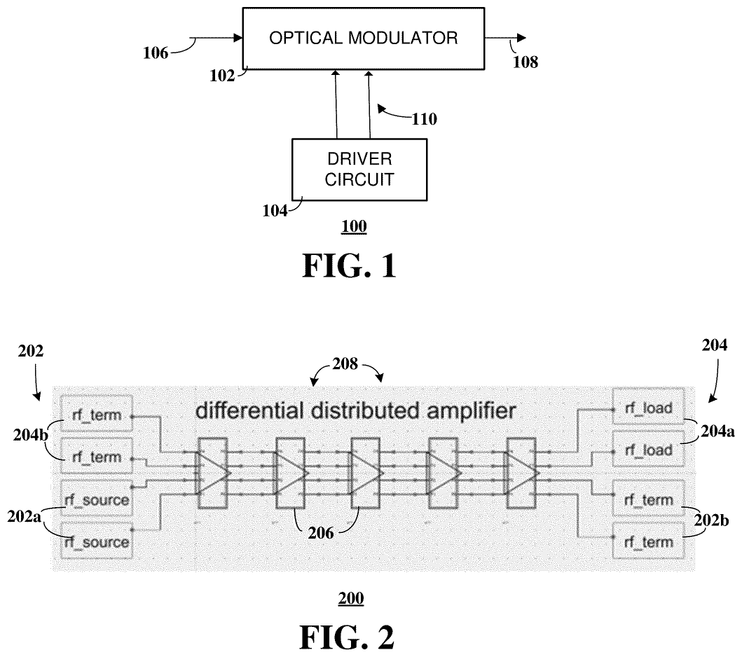

FIG. 1 is a block diagram illustrating an exemplary, non-limiting embodiment of an optical transmission unit 100 in accordance with various aspects described herein. In the illustrated embodiment, the optical transmission unit 100 includes an optical modulator 102 and a driver circuit 104. The optical modulator 102 receives an input light signal at an input 106. The optical modulator 102 modulates the input light signal to produce an output signal at an output 108. Modulation is according to a modulation signal 110 received from the driver circuit 104. In embodiments, the optical modulator may be of the Mach-Zehnder (MZ) type or any other suitable modulation device.

Long distance optical communications use light beams conveyed through optical fibers to transmit data and other information. Optical communications permits data rates up to 1.6 Tbps and beyond. Each end of the optical fiber requires a modulator or demodulator for conversion between electronic data and optical data. Thus, a key part of an optical transmission system is a modulation scheme to put the data onto a light beam. Such modulation is conventionally performed by an optical modulator that is driven by a driver circuit, as in the optical transmission unit 100. One example of an optical modulator is disclosed in co-pending U.S. patent application Ser. No. 18/895,655 (having Attorney Docket No. 10.3256 CIENA-2450A), filed on Sep. 25, 2024, which is incorporated herein in its entirety by this reference. One or more of the embodiments described herein can be combined in whole or in part with the embodiments described in the incorporated application.

A suitable driver circuit may require a substantially flat frequency response from near DC up to several hundred gigahertz. A suitable driver circuit must also generate a substantial amount of power to drive the current optical modulator technology, including providing a full output voltage swing. Moreover, some current generation optical modulators employ differential drive so the driver circuit generally must provide differential drive as well. Differential drive reduces the required amount of output voltage swing or peak-to-peak output voltage. However, the differential drive for a driver circuit may require a bandwidth greater than 100 GHz and output voltage greater than 4 volts peak to peak.

Driver circuits are manufactured in integrated circuits using conventional semiconductor manufacturing technology. Previous generations used silicon technology because the technology is well-developed and well-understood. However, silicon circuits generally have a breakdown voltage too small to support 4-volt peak to peak signals. Accordingly, a suitable driver circuit may require a switch to an alternative semiconductor technology. One example is indium phosphide (InP). Circuits of indium phosphide generally have a good combination of high frequency performance and breakdown voltages.

FIG. 2 is a block diagram illustrating an exemplary, non-limiting embodiment of an amplifier 200 in accordance with various aspects described herein. In the illustrated embodiment, the amplifier 200 is a differential distributed amplifier. The amplifier 200 may be used in a very high-performance circuit for amplifying electrical signals. For example, in the optical transmission unit 100, the amplifier 200 may be used to implement embodiments of the driver circuit 104. In exemplary embodiments, the amplifier 200 may have a bandwidth of 100 GHz or more and an output voltage swing of 4 V peak to peak.

The amplifier 200 includes an input 202, an output 204 and a plurality of stages 206. A distributed amplifier such as amplifier 200 is a type of electronic amplifier that uses transmission lines to distribute the input signal across multiple amplifier stages. This design approach allows for a wider bandwidth and higher gain compared to traditional amplifiers. In the exemplary embodiment, the amplifier 200 is formed in a single integrated circuit of a suitable semiconductor material such as indium phosphide.

The input signal is received at the input 202, divided and fed into the plurality of stages 206. In one example, the amplifier 200 includes ten stages. In other embodiments, any suitable number may be used. The plurality stages 206 are connected in parallel. Transmission lines 208 are used to connect the input and output stages. The transmission lines 208 may be in transmission line segments coupling respective inputs or outputs. These lines act as delay lines, ensuring that the signals arrive at each stage at the correct time. Each respective amplifier stage amplifies the portion of the signal it receives. The amplified signals are then combined at the output 204, resulting in a significantly amplified version of the original input signal received at the input 202. Amplification among the multiple stages is additive.

Distributed amplifiers such as the amplifier 200 are able to operate over a wide frequency range, including 100 GHz and beyond. By combining the amplification from the plurality of stages 206, the amplifier can achieve high gain, including a gain adequate for use in a driver circuit for an optical amplifier.

In FIG. 2, the input 202 includes a differential radio frequency (RF) source 202a and a differential RF terminator 202b. Similarly, the output 204 includes a differential RF load 204a and a differential RF terminator 204b. The respective terminations and loads provide proper termination for the transmission lines 208, for example, to eliminate destructive reflections on the transmission lines 208. The differential RF load 204a may include or be coupled to the differential input of an optical modulator such as optical modulator 102 of FIG. 1. In design, the transmission delay between the stages is properly the same on the input side and the output side so that the outputs add up properly without a phase shift.

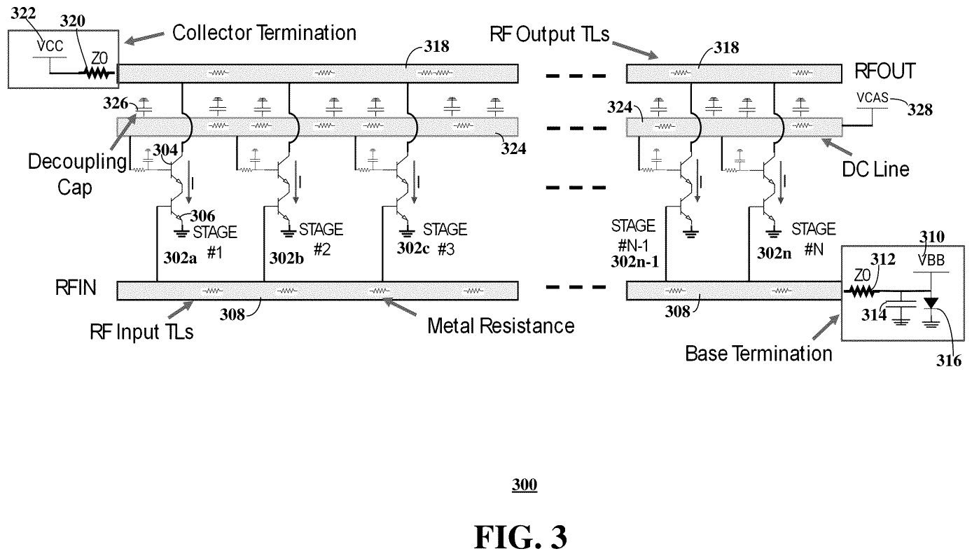

FIG. 3 is a block diagram illustrating conventional single-ended N-stage distributed amplifier circuit 300. In FIG. 3, the single-ended N-stage distributed amplifier circuit 300 includes a plurality of amplification stages including first stage 302a, second stage 302b, third stage 302c and N-th stage 302n. Any suitable number of stages may be used in the N-stage distributed amplifier circuit 300. In one example, the N-stage distributed amplifier circuit 300 includes ten single-ended stages. Each respective stage includes a cascode connected transistor pair including, in the example of first stage 302a, a first transistor 304 and a second transistor 306. In this configuration, the upper common base stage including first transistor 304 provides a low impedance for the lower stage including second transistor 306 so that the voltages generated on the nodes connecting upper stage and the lower stage are minimized.

The lower stage transistors of each stage, such as transistor 306, are commonly connected at their respective base terminals to a radio frequency input (RFIN) on input node 308. The input node 308 is biased to a DC bias voltage V_{BB} 310 through a resistor 312. A decoupling capacitor 314, in parallel with a diode 316, along with the resistor 312, forms a base termination to V_{BB} 310 for the input node 308. The diode 316 may be formed, for example, from a base-emitter junction substantially identical to the base-emitter junctions of the NPN transistors used throughout the amplifier circuit 300.

Similarly, the upper stage transistors of each stage, such as transistor 304, are commonly connected to a radio frequency output (RFOUT) on output node 318. The output node 318 is coupled through a resistor 320 to the DC power supply V_{CC} 322.

The bases of the upper-level transistors of each respective stage, such as transistor 304, are coupled to a VCAS bias node 324. In the example embodiment, multiple decoupling capacitors such as capacitor 326 provide an AC path to ground from the VCAS bias node 324. The VCAS bias node 324 is tied to a bias voltage VCAS 328.

Each stage of the N-stage distributed amplifier circuit 300 may be characterized by a current flowing in the upper transistor 304 and the lower transistor 306. This current is labelled I in FIG. 3. Generally, the current I should have the same magnitude in each stage of the amplifier circuit 300.

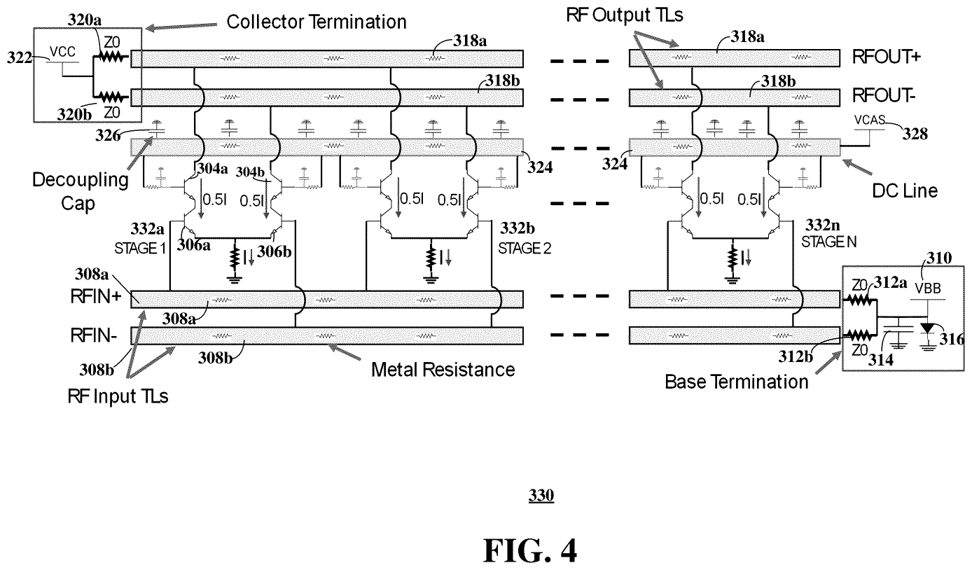

FIG. 4 is a block diagram illustrating a differential N-stage distributed amplifier circuit 330. In FIG. 4, the differential N-stage distributed amplifier circuit 330 includes a plurality of amplification stages including first stage 332a, second stage 332b, third stage 302c and N-th stage 302n. Any suitable number of stages may be used in the differential N-stage distributed amplifier circuit 330. In one example, the differential N-stage distributed amplifier circuit 330 includes five differential stages. Each respective stage includes a cascode connected transistor pair including, in the example of first stage 302a, a first transistor 304 and a second transistor 306. Each respective stage may be termed a differential cascode amplifier.

As an example, the first stage 332a is configured as a differential amplifier. The differential amplifier of stage 332a includes two common emitter connected transistors including a first transistor 306a and a second transistor 306b, and a tail resistor coupling the common emitter node to ground to provide a biasing current. The common emitter transistors feed into a pair of common base transistors including transistor 304a and transistor 304b. The emitter of transistor 304a is coupled to the collector of transistor 306a. The emitter of transistor 304b is coupled to the collector of transistor 306b. A capacitor and resistor in the base of the transistor 304a is used for RF matching to ensure the desired gain is achieved.

The lower common emitter transistors of each stage, such as transistor 306a and 306b, are commonly connected at their respective base terminals to a differential radio frequency input (RFIN+ and RFIN−) on input node 308a and input node 308b. The input node 308a and the input node 308b are biased to a DC bias voltage V_{BB} 310 through a resistor 312 and a resistor 312b, respectively. A decoupling capacitor 314 in parallel with a diode 316, along with the resistor 312a and the resistor 312b, forms a base termination to V_{BB} 310 for the input node 308a and the input node 308b. The diode 316 may be formed, for example, from a base-emitter junction substantially identical to the base-emitter junctions of the NPN transistors used throughout the amplifier circuit 330.

Similarly, the upper stage transistors of each stage, such as transistor 304a and transistor 304b, are commonly connected to a differential radio frequency output (RFOUT+ and RFOUT−) on output node 318a and output node 318b. The output node 318a and the output node 318b are coupled through respective resistor 320a and resistor 320b to the DC power supply V_{CC} 322.

The bases of the upper-level transistors of each respective stage, such as transistor 304a and transistor 304b, are coupled to a VCAS bias node 324. In the example embodiment, multiple decoupling capacitors such as capacitor 326 provide an AC path to ground from the V_{CAS} bias node 324 to reduce noise on the DC bias node. The VCAS bias node 324 is tied to a bias voltage V_{CAS} 328.

Each stage of the N-stage distributed amplifier circuit 330 may be characterized by a current flowing in the upper transistors 304a, 304b and the lower transistors 306a, 306b. The current may be established by a tail resistor coupled to the common emitter node of the two lower transistors 306a, 306b or by any other suitable current source. This current is labelled I in FIG. 4. Generally, the current I should have the same magnitude in each stage of the amplifier circuit 330 and, in each stage, the current I should split through the cascode-connected transistor pairs so that a current I/2 flows in a lower transistor 306a and an upper transistor 304a and a current I/2 flows in the lower transistor 306b and the upper transistor 304b.

In practical embodiments, the N-stage distributed amplifier circuit 300 of FIG. 3 and the N-stage distributed amplifier circuit 330 of FIG. 4 may be manufactured in integrated circuits using conventional semiconductor manufacturing technology. Generally, for such circuits, active devices such as transistors and passive devices such as resistors are formed in the top layers of a semiconductor material, such as silicon or Indium Phosphide. For electrical interconnections, one or more high-conductivity metallic layers are formed on the surface of the semiconductor and make electrical contact to the semiconductor devices.

Each device and each layer may be defined by geometric shapes that form the required shapes in the integrated circuit during manufacturing. For computer aided design, a library of common structures may be used, including, for example, the layout of the devices that form a common cell such as each individual stage of the distributed amplifier circuit 300, 330. Each stage of the N-stage amplifier circuit is substantially identical in performance, so the geometric structures that define the stages may be identical. The common cell includes identical geometries defining some structures that are unique to each cell such as, for example, an emitter region and a base region and a metal contact of a single transistor in the amplifier stage defined by the common cell. Further, the common cell includes identical geometries defining some other structures that are common to each cell, such as a metal interconnection line that is commonly connected to all cells at a common circuit location and a common geometrical point, such as a transistor base terminal electrically tied to V_{CAS}.

When designing an integrated circuit, the required cells are laid out or arranged using computer aided design tools. In the example of the distributed amplifier circuit, to simplify the layout and minimize parasitic interactions, the identical cell may be placed repeatedly in a line to together form the stages of the N-stage amplifier circuit. The identical cells are generally arranged in a linear array across the surface of an integrated circuit to take advantage of common connections. For example, each stage of the N-stage amplifier requires metal connections to power supply V_{CC} and ground, as well as to DC bias nodes such as VBB and V_{CAS}. Similarly, each stage of the N-stage amplifier requires metal connections to AC nodes including RFIN (singled ended amplifier) and RFIN+ and RFIN− (differential amplifier). Thus, each of these DC bias nodes and AC signal nodes extends along the length of the overall structure that forms the N-stage amplifier circuit 300, 330.

In operation, the single-ended N-stage distributed amplifier circuit 300 of FIG. 3 and the differential. N-stage distributed amplifier circuit 330 of FIG. 4 may operate at relatively high frequencies to drive circuits such as the optical modulator 102 (FIG. 1). A radio frequency input signal is received at the input, labelled RFIN or RFIN+, RFIN−. The input signal, at 100 GHz or greater frequency, is amplified by the N-stage differential amplifier and produces an amplified output signal at the node RFOUT or RFOUT+, RFOUT−.

For operation at high frequencies such as greater than 100 GHz, the N-stage amplifier circuit 300, 330 requires higher gain. To increase the amplifier gain, the number of amplifier stages may be increased. Any suitable number of amplifier stages may be used, such as 5 stages. Adding more stages, while increasing overall gain, also extends the physical size of the N-stage amplifier structure, thereby extending the length of the DC bias nodes and AC signal nodes. As the DC bias lines become longer and longer, at high frequency the DC bias lines act like transmission lines. The RF signal from the RF input or the RF output, or parasitically through other materials of the circuit, becomes coupled onto the DC bias lines including the line carrying the DC voltage V_{CAS} and the base termination V_{BB}. The result may be resonances on the DC bias lines and oscillation of the DC bias voltages.

The DC lines behave like transmission lines at very high frequencies. As illustrated in FIG. 3, for example, the metal lines conveying the DC voltages and RF input and output have a finite resistivity, expressed in Ohms per centimeter, illustrated in the drawing as small resistors in the metal DC bias lines and AC signal lines. This gives rise to a non-zero metal resistance in the metal lines, and it is proportional to the length of the line. The DC line can act as an RF transmission line at high frequency, where the distributed inductance, decoupling capacitors such as capacitor 326, metal resistivity and dielectric constants determine the transmission line wave behavior. A coupled RF signal on a DC line (incident wave) can generate a reflected RF signal at the low impedance (short) termination. If the reflected wave interferes constructively with an incident wave, a standing wave may form, amplifying voltage and current and causing oscillation.

A second issue relates to voltage drops along the metal conductors of the amplifier circuit 300, 333. As noted, each stage of the N-stage amplifier has a current for biasing the amplifier of the stage. Preferably, the current should be a fixed constant value for each stage for linearity. As shown in FIG. 3 and FIG. 4, the base of the lower transistors, such as transistor 302, of the cascode pair is fed by the DC voltage V_{BB} 310 through the RF input line 308. Further, the base of the upper cascode transistor, such as transistor 304, is fed by the DC voltage V_{CAS} 328 through the DC line and the supply voltage V_{CC} is applied to the collector of cascode transistors through the RF output transmission line 318.

Because of the metal resistivity, the iR voltage drop for the third stage 302c is different from the iR voltage drop for the first stage 302a or the second stage 302b. The target is to have a constant value for each respective stage, but because of the metal resistivity on the RF lines and DC lines, there is an IR drop. Thus, the voltage V_{BB} 310 is provided to the RFIN line 308 at one end of the RFIN line 308 but the voltage is subject to iR drops along its length. Similarly, the bias voltage V_{CAS} 328 is provide to the bias line 324 but is subject to iR drops along its length.

Accordingly, increasing the number of stages in the distributed amplifier can lead to DC voltage drop along RF input transmission line 308, the RF output transmission line 318 and DC lines including the DC voltage V_{CAS} 328, the base termination DC voltage V_{BB} 310. This voltage drop is primarily due to metal resistivity. These voltage drops along the metal lines running the length of the N-stage amplifier circuit structure on the integrated circuit can impact the bias condition of each stage of the N-stage amplifier. As a result, the total voltage drop may accumulate, leading to significant variations in biasing between first stage 302a and last stage 302n. This non-uniform biasing between gain stages of the N-stage amplifier causes distributed amplifier performance issues such as high nonlinearity. As noted, preferably the current should be a fixed constant value for each stage for linearity. But due to the arrangement of the circuit elements and the finite iR drop along the metal lines, the result is non-linearity.

Thus, one design goal is to have a constant value for current through all stages of the N-stage distributed amplifier 300, 330 to maintain a constant and equal bias point for each respective stage. But because of the metal resistivity between the location of, for example, the source of the V_{BB} 310 bias voltage and the source of the V_{CAS} 328 bias voltage, the values of the bias voltages, input RF voltage and output RF voltage change along the length of the distributed amplifier 300, 330. Accordingly, achieving the noted design goal requires reduction and minimization of the iR drops seen by each stage and the bias operating points set for each stage based on the biasing.

As indicated in the drawing figures, conventionally DC voltages are fed to a distributed amplifier circuit such as the single ended distributed amplifier circuit 300 and the differential distributed amplifier circuit 330 from one side or the other of the circuit. As noted, conventionally, the graphical CAD structures of the physical integrated circuit are laid out side by side so that common shapes and common electrical features, such as a DC bias metallization, are aligned on the completed circuit. This enables a spatially efficient layout, a smaller circuit, less parasitic circuit effects and better production yield from the manufacturing process.

In the example of FIG. 3, in the conventional single ended distributed amplifier circuit 300, the V_{CC} 322 voltage is fed from the left-hand side to the RF output line 318. Similarly, the V_{CAS} 328 voltage is fed to the bias line 324 from the right-hand side and the VBB 310 voltage is fed to the RFIN line 308 from the right-hand side. In the same way, in FIG. 4, in the conventional differential distributed amplifier circuit 330, the V_{CC} 322 voltage is fed from the left-hand side to the RFOUT+ line 318a and the RFOUT− line 318b. Similarly, the V_{CAS} 328 voltage is fed to the bias line 324 from the right-hand side. And similarly, the VBB 310 voltage is fed to the RFIN+ line 308a and RFIN− line 308b from the right-hand side. As noted, this arrangement leads to variable current-resistance (iR) voltage drops along the length of the DC and AC metal conductors. These iR drops can impact the bias condition of each stage individually and differently. The total voltage drop along the length of the metallization may accumulate or combine linearly. This can lead to significant variations in biasing between first stage (stage 1) and last stage (stage N). This non-uniform biasing between gain stages causes performance issues for the distributed amplifier circuit such as high nonlinearity.

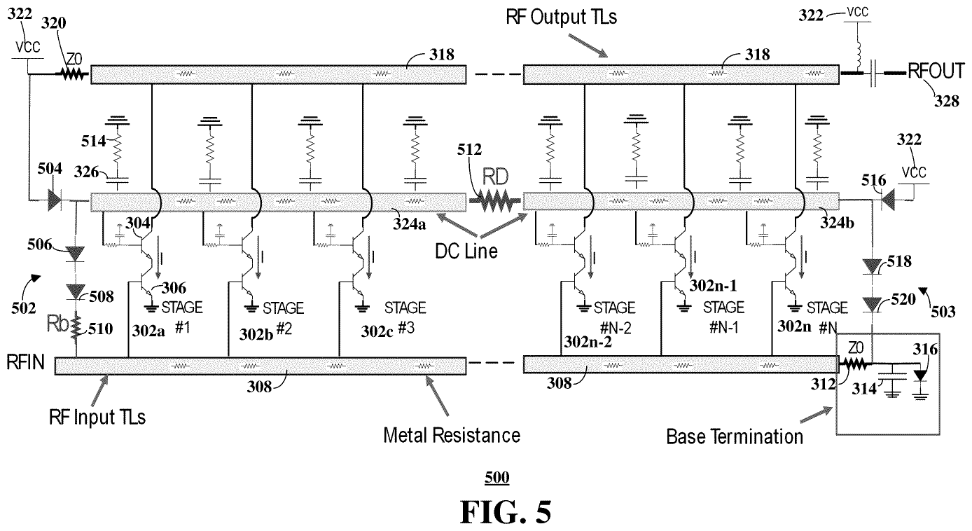

FIG. 5 is a block diagram illustrating an exemplary, non-limiting embodiment of a single-ended N-stage distributed amplifier circuit 500 in accordance with various aspects described herein. FIG. 5 illustrates a single-ended N-stage differential amplifier circuit 500 designed to address challenges related to parasitic effects and voltage drops in high-frequency applications. The circuit is configured with multiple amplification stages, including a first stage 302a, a second stage 302b, a third stage 302c, and up to an n-th stage 302n. The stages are each arranged in a cascode configuration to provide high gain and wide bandwidth. Any number of stages may be used, such as 10, to provide the necessary gain for the distributed amplifier.

The distributed amplifier circuit 500 receives a radio frequency (RF) input signal. The RF input signal is introduced at the RFIN node 308 and distributed across the amplifier stages via RF input transmission line 308. This RF input transmission line is designed with specific characteristic impedances to ensure minimal signal reflection and loss, acting as a delay line to synchronize the input signal across each stage.

An input biasing network 502 at the left end of the circuit 500 includes diode 504, diode 506, diode 508 and R_{b} resistor 510. Diode 504 is coupled between the power supply level V_{CC} 322 and the DC bias line 324a. Diode 506 and diode 508 are series-coupled from the DC bias line 324a to a common node with R_{b} resistor 510. In some embodiments, the diodes 506 and diode 508 may be formed from base-emitter junctions of typical NPN transistors used in the circuit 500 so as to track with other circuit components with variations in supply voltage, temperature and manufacturing conditions. R_{b} resistor 510a couples the common node to RFIN+ node 308a and R_{b} resistor 510b couples the common node to the RFIN− node 308b. A large value, such as a value greater than 2 kOhm has been chosen for R_{b} resistor 510 to ensure that the input impedance matching is not compromised. In normal operation, there is very little current through the R_{b} resistor 510.

A base termination circuit provides biasing at the right end of the RFIN line 308. The base termination circuit includes a resistor 312 between the end of the RFIN line 308 and a biasing node. A diode 316 is positioned between the biasing node and ground, in parallel with a capacitor 314. A biasing circuit 503 matches the biasing circuit 302 and includes a diode 516, a diode 518 and a diode 520. The diode 516 is positioned between the power supply V_{CC} 322 and the DC bias line 324b. Diode 518 and diode 520 are series-coupled from the DC bias line 324b to the biasing node with resistor 312. In some embodiments, the diodes 506 and diode 508 may be formed from base-emitter junctions of typical NPN transistors.

The power supply voltage V_{CC} 322 is coupled to both the left and right side of the RFOUT output node 318. A current limiting resistor 320, having any suitable resistance value, is coupled between V_{CC} 322 and the RFOUT output node 318 at the left-hand side. The RFOUT output node 318 is continuous and is coupled without a break to each stage of the N-stage amplifier. In particular, the RFOUT output node 318 is coupled to the collector of the upper transistor such as transistor 304 of each cascode stage. An amplifier output RFOUT 328, is coupled to the RFOUT node through a capacitor. The RFOUT output node 318 operates as a transmission line to conduct high frequency (such as 100 GHz) amplified output signals from the distributed amplifier circuit 500.

The RF output node 318 collects the amplified signals from each stage and combines them to produce a significantly amplified output signal at the RFOUT node 328. The RF output node 318, like the input transmission lines, are designed with specific characteristic impedances to minimize reflections and losses.

Line 324a and line 324b are used for biasing the stages of the distributed amplifier circuit 500. Line 324a is split from line 324b and the two lines are electrically isolated by resistor RD 512. Any suitable value may be used for the resistor RD 512.

The voltage V_{CAS} of FIG. 3 has been replaced by a DC bias voltage on line 324a and line 324b in the embodiment of the distributed amplifier circuit 500 of FIG. 5. The DC bias voltage on line 324a is generated by diode 504 such that, in this embodiment, the DC bias voltage on line 324a has a value of one diode drop below V_{CC}. Any suitable voltage value may be used. The diode 504 may be formed as a base-emitter junction of a conventional NPN transistor. Similarly, the DC bias voltage on line 324b is generated by diode 516 such that, in this embodiment, the DC bias voltage on line 324b has a value of one diode drop below the supply voltage of V_{CC}. In embodiments, the diode 504 and the diode 516 are manufactured substantially identically so that the DC bias voltage on line 324a and line 324b will track together with temperature, supply voltage and manufacturing process variations.

Any suitable voltage value may be used for the DC bias voltage on line 324a and the DC bias voltage on line 324b. The DC bias voltage on line 324a and DC bias voltage on line 324b supply the necessary DC bias voltages to the amplifier stages. In particular, the DC bias voltage on line 324a and line 324b is provided to the base terminal of the upper transistors, such as transistor 304, of the cascode pairs of each stage of the N-stage amplifier. The DC bias voltage on line 324a and line 324b is thus used for setting the operating point of the transistors and ensuring linear amplification.

The double-sided DC feeding technique is employed to mitigate current-resistance (iR) voltage drops along the DC line 324a and line 324b by feeding the DC bias from both ends of the amplifier circuit 500. This minimizes the voltage drop due to metal line resistivity and ensures uniform biasing across all stages of the amplifier circuit.

The distributed amplifier circuit 500 aims to minimize the effects of metal resistivity and ensure stable operation at high frequencies, making the amplifier suitable for driving high-performance components such as optical modulators in communication systems. Each amplification stage, from the first stage 302a to the n-the stage 302n, is configured in a cascode arrangement, a two-transistor configuration that provides high gain and wide bandwidth. This configuration minimizes the Miller effect, enhancing the frequency response of the amplifier. The stages are connected in parallel, allowing the RF input signal to be distributed across them, achieving higher overall gain and bandwidth by combining the amplified signals at the output. A split DC bias line, including line 324a and line 324b, is responsible for supplying the necessary DC bias voltages to the amplifier stages, for setting the operating point of the transistors and ensuring linear amplification. The double-sided DC feeding technique mitigates iR drops along the DC line by feeding the DC bias from both ends of the amplifier, minimizing voltage drop due to metal line resistivity and ensuring uniform biasing across all stages, which is crucial for consistent performance and linearity.

The distributed amplifier circuit 500 includes a series resistor 514 along with decoupling capacitors 326. These components operate to damp high frequency resonances on the DC line 324a and the DC line 324b. In the example embodiment, a capacitor 326 and resistor 514 extend between the DC biasing line 324a and ground. Each stage of the N-stage amplifier circuit 500 includes a decoupling capacitor 326 and a resistor 514. In embodiments, the decoupling capacitor 326 and the resistor 514 may be incorporated in the circuit layout of the stage structure, since the nodes at either end of the decoupling capacitor 326 and the resistor 514, the DC line and ground, are common and extend across the length of the amplifier circuit 500. Similar structure is repeated for stages coupled to DC bias line 324b.

The DC line 324a and the DC line 324b are separated by a RD resistor 512 in the middle of the DC bias line. The RD resistor 512 may have any suitable value, such as 50 Ohms. The RD resistor 512 acts as a damping element to prevent unwanted oscillation caused by interaction between incident and reflected waves, coupled from the RF path through the distributed amplifier circuit 600. Since the DC line 324a and the DC line 324b are biased similarly, the voltage drop across the damping resistor 512 is negligible and this element keeps the voltage at the terminals, including DC line 324a and DC line 324b, nearly equal.

Metal resistance represents the inherent resistive properties of the metal lines used in the circuit, which at high frequencies can lead to voltage drops affecting biasing and performance. The design aims to minimize these effects through careful layout and material selection. The base termination, including resistor 312, capacitor 314 and diode 316, operates to prevent destructive reflections that can lead to instability and performance degradation. The resistive and capacitive elements provide a matched load to the transmission lines, ensuring stable operation.

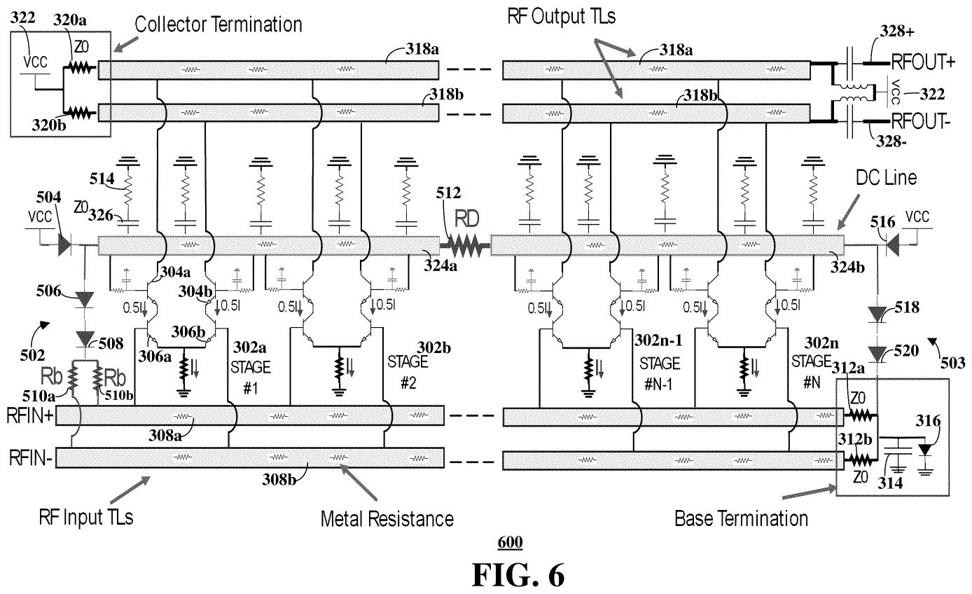

FIG. 6 is a block diagram illustrating an exemplary, non-limiting embodiment of a differential N-stage differential amplifier circuit 600 in accordance with various aspects described herein. Embodiments of the differential N-stage distributed amplifier circuit 600 are designed to enhance performance in high-frequency applications by addressing parasitic effects and voltage drops. The circuit 600 is configured with multiple amplification stages, including in this example, first stage 302a, second stage 302b, through n-th stage 302n, arranged in a cascode configuration to provide high gain and wide bandwidth. Any suitable number of stages may be used. In one example, five stages are used in an embodiment of the circuit 600.

Differential RF input signals are introduced at the RFIN+ node 308a and RFIN− node 308b. These differential input nodes are distributed across the amplifier stages via RF input transmission lines. These transmission lines are designed with specific characteristic impedances to ensure minimal signal reflection and loss, acting as delay lines to synchronize the input signals across each stage.

An input biasing network 502 at the left end of the circuit 600 includes diode 504, diode 506, diode 508 and R_{b} resistor 510a and R_{b} resistor 510b. Diode 504 is coupled between the power supply level V_{CC} 322 and the DC bias line 324a. Diode 506 and diode 508 are series-coupled from the DC bias line 324a to a common node with R_{b} resistor 510a and R_{b} resistor 510b. In some embodiments, the diodes 506 and diode 508 may be formed from base-emitter junctions of typical NPN. R_{b} resistor 510a couples the common node to RFIN+ node 308a and R_{b} resistor 510b couples the common node to the RFIN− node 308b. A large value, such as a value greater than 2 kOhm has been chosen for R_{b} resistor 510a and R_{b} resistor 510b to ensure that the input impedance matching is not compromised. In normal operation, there is very little current through the R_{b} resistor 510a and R_{b} resistor 510b, such as base current to drive the NPN transistors in each stage of the amplifier circuit 500.

A base termination circuit provides biasing at the right end of the RFIN+ line 308a and the RFIN− line 308b. The base termination circuit includes a resistor 312a between the end of the RFIN+ line 308a and a biasing node and a resistor 312b between the end of the RFIN− line 308b and the biasing node. A diode 316 is positioned between the biasing node and ground, in parallel with a capacitor 314. A biasing circuit 503 matches the biasing circuit 302 and includes a diode 516, a diode 518 and a diode 520. The diode 516 is positioned between the power supply V_{CC} 322 and the DC bias line 324b. Diode 518 and diode 520 are series-coupled from the DC bias line 324b to the biasing node with resistor 312. In some embodiments, the diodes 506 and diode 508 may be formed from base-emitter junctions of typical NPN transistors.

Line 324a and line 324b are used for biasing the stages of the distributed amplifier circuit 500. Line 324a is split from line 324b and the two lines are electrically isolated by resistor RD 512. Any suitable value may be used for the resistor RD 512.

The voltage V_{CAS} of the conventional differential distributed amplifier illustrated in FIG. 4 has been replaced by a DC bias voltage on line 324a and DC bias voltage line 324b in the embodiment of the distributed amplifier circuit 600 of FIG. 6. The DC bias voltage on line 324a is generated by diode 504 such that, in this embodiment, the DC bias voltage on line 324a has a value of one diode drop below supply voltage V_{CC}. Any suitable voltage value for the DC bias voltage may be used. The diode 504 may be formed as a base-emitter junction of a conventional NPN transistor. Similarly, the DC bias voltage on line 324b is generated by diode 516 such that, in this embodiment, the DC bias voltage on line 324b has a value of one diode drop below the supply voltage of V_{CC}. In embodiments, the diode 504 and the diode 516 are manufactured substantially identically so that the DC bias voltage on line 324a and line 324b will track together with temperature, supply voltage and manufacturing process variations.

Any suitable voltage value may be used for the DC bias voltage on line 324a and the DC bias voltage on line 324b. The DC bias voltage on line 324a and DC bias voltage on line 324b supply the necessary DC bias voltages to the amplifier stages. In particular, the DC bias voltage on line 324a and line 324b is provided to the base terminal of the upper transistors, such as transistor 304 and transistor 304b, of the cascode pairs of each stage of the N-stage amplifier circuit 600. The DC bias voltage on line 324a and line 324b is thus used for setting the operating point of the transistors and ensuring linear amplification.

The double-sided DC feeding technique is employed to mitigate current-resistance (iR) voltage drops along the DC line 324a and line 324b by feeding the DC bias from both ends of the amplifier circuit 600. This minimizes the voltage drop due to metal line resistivity and ensures uniform biasing across all stages of the amplifier circuit 600.

The power supply voltage V_{CC} 322 is coupled to both the left side and the right side of the RFOUT+ output node 318a and the RFOUT− output node 318b. Current limiting resistor 320a and resistor 320b, having any suitable resistance value, are coupled between V_{CC} 322 and the RFOUT+ output node 318a and the RFOUT− output node 318b at the left-hand side of the circuit 600. The RFOUT+ output node 318a and the RFOUT− output node 318b are continuous and are coupled without a break to each stage of the N-stage amplifier. In particular, the RFOUT+ output node 318a and the RFOUT− output node 318b are coupled to the collectors of the upper transistor such as transistor 304a and transistor 304b of each cascode stage. An amplifier output RFOUT+ 328a and RFOUT− node 328b are coupled to the RFOUT+ output node 318a and the RFOUT− output node 318b through a capacitor. The RFOUT+ output node 318a and the RFOUT− output node 318b operate as transmission lines to conduct high frequency (such as 100 GHz) amplified output signals from the distributed amplifier circuit 600.

The distributed amplifier circuit 600 includes a series resistor 514 along with decoupling capacitors 326. These components operate to damp high frequency resonances on the DC line 324a and the DC line 324b. In the example embodiment, a capacitor 326 and resistor 514 extend between the DC biasing line 324a and ground. Each stage of the N-stage amplifier circuit 500 includes a decoupling capacitor 326 and a resistor 514. In embodiments, the decoupling capacitor 326 and the resistor 514 may be incorporated in the circuit layout of the stage structure, since the nodes at either end of the decoupling capacitor 326 and the resistor 514, the DC line and ground, are common and extend across the length of the amplifier circuit 500. Similar structure is repeated for stages coupled to DC bias line 324b.

The DC line 324a and the DC line 324b are separated by a RD resistor 512 in the middle of the DC bias line. The RD resistor 512 acts as a damping element to prevent unwanted oscillation causing by interaction between incident and reflected waves, coupled from the RF path through the distributed amplifier circuit 600. The RD resistor can have any suitable value such as 50 Ohms. Any voltage drop across the damping resistor 512 is negligible and this element keep the voltage at the terminals, including DC line 324a and DC line 324b, nearly equal.

The RFOUT+ output node 318a and the RFOUT− output node 318b collects the amplified signals from each stage and combine them to produce a significantly amplified output signal at the amplifier output RFOUT+ 328a and RFOUT− node 328b. The RFOUT+ output node 318a and the RFOUT− output node 318b, like the input transmission lines, are designed with specific characteristic impedances to minimize reflections and losses.

In the differential mode response of the differential distributed amplifier circuit 600, due to the presence of a virtual ground at the base of the cascode transistors (e.g., transistor 304a and transistor 304b), the coupled RF signal on the DC line 324a, 324b is weaker compared to the single-ended configuration of single-ended distributed amplifier circuit 500 illustrated in FIG. 5. However, slight phase difference in the differential signals can cause interaction between the incident and reflected waves on the DC lines 324a, 324b, which ultimately results in oscillation.

In the common mode response of the differential distributed amplifier circuit 600, unlike the differential mode, due to the presence of a virtual open circuit at the base of the cascode transistors, the coupled RF signal level on the DC line 324a, 324b is stronger.

The distributed amplifier circuit 600 aims to minimize the effects of metal resistance and ensure stable operation at high frequencies, making the amplifier suitable for driving high-performance components such as optical modulators in communication systems. Additionally, the circuit employs Rb resistors 510a, 510b to further stabilize the biasing network and enhance the differential drive capability, ensuring that the amplifier can effectively handle high-frequency signals with reduced parasitic effects. The use of a differential configuration helps in reducing the required output voltage swing, making the circuit more efficient for optical modulator applications.

Feeding power supply voltages from input and output sides of transmission lines, as illustrated in FIG. 5 and FIG. 6, helps to mitigate the non-uniform bias condition of active devices in the amplification stages of the amplifier circuit 500, 600. This technique reduces the DA nonlinearity characteristics compared to single-side DC supply feeding method. Because the respective stages are biased more similarly or identically (due to elimination of iR drops), the transistor amplifiers operate at a more similar current level across the multiple stages. Since the gains are additive, the increased gain of each stage and the overall distributed amplifier circuit 500, 600 operates more linearly as well. Double-sided DC feeding helps to mitigate the non-uniform bias condition due to iR voltage drops on the metallization, such as the DC bias lines 324a and 324b.

Further, suppressing the unwanted oscillations on DC line 324a, 324b, using a damping resistor without any voltage drop across the element, improves circuit AC performance as well. Any reflection on the DC bias line 324 (FIG. 3, FIG. 4) can cause an oscillation. One solution is to make the DC bias line 324 shorter (FIG. 5, FIG. 6), to send any reflection on the DC bias lines 324a, 324b to a higher frequency. Adding the RD resistor 512 to match the coupled signal operates to terminate the reflected signal so that there is substantially no reflected signal on the DC bias lines 324a, 324b. Placing the damper element RD resistor 512, in the middle of DC line 324a and 324b, will suppress resonances without causing an iR voltage drop. Further, the RD resistor 512 will have no substantial impact on the operation of the amplification stages. The DC bias lines 324a, 324b, are biased to a substantially identical voltage. Even accounting for iR drops from the left end and the right end, respectively, the DC bias line 324a and the DC bias line 324b are at substantially identical voltages. Therefore, the current through RD resistor 512 is substantially 0 at all times.

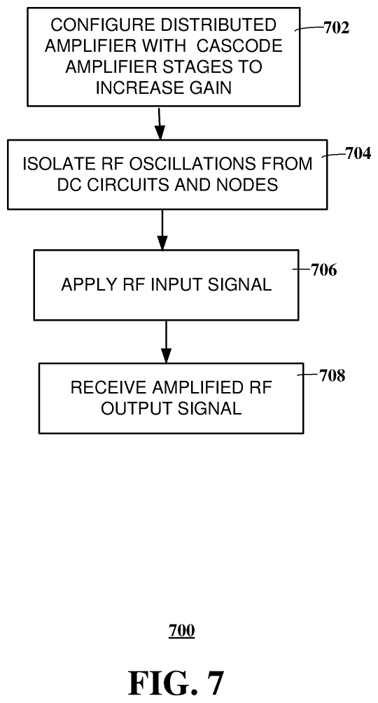

FIG. 7 depicts an illustrative embodiment of a method 700 in accordance with various aspects described herein. The method 700 of FIG. 7 may be suitable to enhance performance in high-frequency applications. The method involves several steps, each linked to the structural and functional aspects of the amplifier circuits 500, 600 shown in FIGS. 5 and 6.

Initially, at step 702, the method 700 involves configuring the distributed amplifier with multiple amplification stages, each arranged in a cascode configuration, as exemplified in FIGS. 5 and 6. This configuration enables achieving high gain and wide bandwidth which are particularly important for high-frequency applications such as optical communications. The stages, labeled as STAGE #1 through STAGE #N, are designed to provide additive amplification, enhancing the overall gain of the circuit.

Step 704 provides for isolating RF oscillations from the DC circuits and nodes, a critical aspect highlighted in FIGS. 5 and 6. In example embodiments, DC bias lines for circuits such as cascode amplifiers may be split into two or more shorter lengths to reduce iR drops due to resistivity of metallization used for integrated circuit manufacture. In some embodiments, a damping resistor such as RD resistor in FIG. 5 and FIG. 6 acts as a damping element to prevent unwanted oscillation caused by interaction between incident and reflected waves on the DC bias line. The double-sided DC feeding technique, along with the use of transmission lines and decoupling components such as the damping resistor, helps to mitigate iR drops and minimize parasitic effects, ensures stable operation at high frequencies. The design aims to prevent destructive reflections and oscillations that could degrade performance.

At step 706, an RF input signal is applied to the amplifier circuit, as depicted by the RFIN and RFIN+ and RFIN− nodes in FIGS. 5 and 6. The input transmission lines are designed to distribute the input signal across the multiple stages, ensuring minimal signal reflection and loss. This step enables synchronizing the input signals across each stage, enabling effective amplification by linearly combining the amplified signals of each stage.

Step 708 involves receiving the amplified RF output signal at the RFOUT and RFOUT+ and RFOUT− nodes, as shown in FIGS. 5 and 6. The RF output transmission lines collect and combine the amplified signals from each stage, producing a significantly amplified output. The design of these lines ensures that reflections and losses are minimized, maintaining the integrity of the amplified signal.

Overall, FIG. 7 outlines a method 700 that leverages the structural and functional innovations of the distributed amplifier circuits in FIGS. 5 and 6, focusing on enhancing gain, stability, and performance in high-frequency applications. The method addresses challenges such as parasitic effects and voltage drops, ensuring that the amplifier circuit operates efficiently and effectively in driving high-performance components like optical modulators.

While for purposes of simplicity of explanation, the respective processes are shown and described as a series of blocks in FIG. 7, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

Several alternate embodiments could be applied to the subject matter of the disclosure. One alternative involves using different semiconductor materials such as gallium arsenide (GaAs) or silicon germanium (SiGe) instead of indium phosphide. These materials may offer different trade-offs in terms of cost, performance, and integration with existing semiconductor processes. Another embodiment could incorporate integrated passive components, such as on-chip inductors and capacitors, to further reduce parasitic effects and enhance the frequency response. This integration could lead to a more compact design and potentially lower manufacturing costs. Additionally, implementing adaptive biasing techniques that dynamically adjust the DC bias voltages based on operating conditions could improve the linearity and efficiency of the amplifier circuit, especially in varying temperature or supply voltage conditions.

For some applications, a modular design approach could also be adopted, allowing for easy scalability of the amplifier circuit. This would enable users to customize the number of amplification stages based on specific application requirements, providing flexibility in gain and bandwidth. Incorporating enhanced feedback mechanisms, such as negative feedback loops, could further stabilize the amplifier circuit and reduce distortion, which would be particularly useful in applications demanding high linearity and low noise.

Adding digital control interfaces to the amplifier circuit could allow for real-time adjustments and monitoring of performance parameters, which would be advantageous in adaptive systems where conditions change dynamically. Finally, for optical communication applications, the amplifier circuit could be integrated with photonic components such as modulators or detectors on a single chip. This integration would reduce interconnect losses and improve overall system efficiency. These alternate embodiments provide various pathways to enhance the functionality, performance, and adaptability of the distributed amplifier circuit, catering to a wide range of high-frequency applications.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. An amplifier circuit, comprising:
a plurality of amplification stages arranged to receive a radio frequency (RF) input signal and provide an amplified output signal;
a double-sided DC feeding system configured to supply DC bias voltages to the plurality of amplification stages from both ends of the amplifier circuit, thereby reducing current-resistance (iR) voltage drops in a DC bias line;
an input transmission line interconnecting the plurality of amplification stages, the input transmission line configured to distribute the RF input signal from an input of the amplifier circuit to each respective amplification stage of the plurality of amplification stages; and
an output transmission line interconnecting the plurality of amplification stages, the output transmission line configured to combine respective output signals of the respective amplification stages and provide the amplified output signal at an output of the amplifier circuit.

2. The amplifier circuit of claim 1, wherein the plurality of amplification stages are arranged in an amplifier structure having a first end and a second end, and wherein the double-sided DC feeding system comprises:
a first bias circuit to provide a first DC bias voltage from the first end of the amplifier structure to a first set of amplification stages of the plurality of amplification stages; and
a second bias circuit to provide a second DC bias voltage from the second end of the amplifier structure to a second set of amplification stages of the plurality of amplification stages, wherein the second DC bias voltage matches the first DC bias voltage.

3. The amplifier circuit of claim 2, wherein the first bias circuit comprises a first diode coupled between a power supply voltage and a first DC bias line, and wherein the first DC bias line is coupled to the first set of amplification stages to provide the first DC bias voltage to the first set of amplification stages; and wherein the second bias circuit comprises a second diode coupled between the power supply voltage and a second DC bias line, and wherein the second DC bias line is coupled to the second set of amplification stages to provide the second DC bias voltage to the second set of amplification stages.

4. The amplifier circuit of claim 2, wherein the double-sided DC feeding system comprises:
first metallization electrically coupling the first set of amplification stages of the plurality of amplification stages and the first bias circuit to provide the first DC bias voltage to respective amplification stages of the first set of amplification stages of the plurality of amplification stages; and
second metallization electrically coupling the second set of amplification stages of the plurality of amplification stages and the second bias circuit to provide the second DC bias voltage to respective amplification stages of the second set of amplification stages of the plurality of amplification stages.

5. The amplifier circuit of claim 4, wherein the double-sided DC feeding system comprises:
a damping resistor electrically coupling the first metallization and the second metallization, the damping resistor having a value selected to damp resonance voltages on the first metallization and the second metallization.

6. The amplifier circuit of claim 1, wherein each respective amplification stage of the plurality of amplification stages comprises:
a plurality of transistors arranged in a cascode arrangement to amplify the RF input signal.

7. The amplifier circuit of claim 6, wherein the plurality of transistors comprises:
a first transistor coupled to the input of the amplifier circuit to receive the RF input signal; and
a second transistor having a first terminal connected to the first transistor, a second terminal connected to the DC bias line and a third terminal connected to the output transmission line.

8. The amplifier circuit of claim 1, wherein each respective amplification stage of the plurality of amplification stages comprises:
a differential amplification stage having a first differential input coupled to a first differential amplifier input of the amplifier circuit, and a second differential input coupled to a second differential amplifier input of the amplifier circuit.

9. The amplifier circuit of claim 1, further comprising:
a first input biasing circuit including an impedance matching resistor coupled to the input transmission line, wherein the first input biasing circuit is physically coupled to a first end of the input transmission line to provide an input DC biasing voltage to the input transmission line; and
a second input biasing circuit coupled to a second end of the input transmission line to provide the input DC biasing voltage to the input transmission line.

10. The amplifier circuit of claim 9, wherein the first input biasing circuit comprises:
one or more diodes coupled between a power supply voltage and the impedance matching resistor.

11. A distributed differential amplifier, comprising:
a plurality of amplification stages arranged in an amplifier structure having a first end and a second end, an amplification stage of the plurality of amplification stages comprising:
a plurality of transistors arranged in a cascode arrangement to amplify a radio frequency (RF) input signal and produce an amplified output signal;
a double-sided DC feeding system configured to supply DC bias voltages to the plurality of amplification stages from the first end of the amplifier structure and from the second end of the amplifier structure of the distributed differential amplifier, thereby reducing current-resistance (iR) voltage drops in a DC bias line;
an input transmission line interconnecting the plurality of amplification stages, the input transmission line configured to distribute the RF input signal from an input of the distributed differential amplifier to each respective amplification stage of the plurality of amplification stages;
a first input biasing circuit physically coupled to the input transmission line at the first end of the amplifier structure to provide a first input DC biasing voltage to the input transmission line; and
a second input biasing circuit physically coupled to the input transmission line at the second end of the amplifier structure to provide a second input DC biasing voltage to the input transmission line.

12. The distributed differential amplifier of claim 11, wherein the double-sided DC feeding system comprises:
a first bias circuit to provide a first DC bias voltage to a first set of amplification stages of the plurality of amplification stages; and
a second bias circuit to provide a second DC bias voltage to a second set of amplification stages of the plurality of amplification stages, wherein the second DC bias voltage matches the first DC bias voltage.

13. The distributed differential amplifier of claim 12, wherein the double-sided DC feeding system comprises:
first metallization electrically coupling the first set of amplification stages of the plurality of amplification stages and the first bias circuit to provide the first DC bias voltage to respective amplification stages of the first set of amplification stages of the plurality of amplification stages; and
second metallization electrically coupling the second set of amplification stages of the plurality of amplification stages and the second bias circuit to provide the second DC bias voltage to respective amplification stages of the second set of amplification stages of the plurality of amplification stages.

14. The distributed differential amplifier of claim 13, wherein the double-sided DC feeding system comprises:
a damping resistor electrically coupling the first metallization and the second metallization, the damping resistor having a value selected to damp resonance voltages on the first metallization and the second metallization.

15. The distributed differential amplifier of claim 11, wherein each respective amplification stage of the plurality of amplification stages:
a first transistor coupled to the input transmission line of the distributed differential amplifier to receive the RF input signal; and
a second transistor having a first terminal connected to the first transistor, a second terminal connected to the DC bias line and a third terminal connected to an output transmission line of the distributed differential amplifier.

16. A distributed amplifier circuit, comprising:
a plurality of amplification stages, each amplification stage of the plurality of amplification stages configured in a cascode arrangement to receive a radio frequency (RF) input radio frequency signal and provide an output signal;
an input transmission line interconnecting the plurality of amplification stages, the input transmission line configured to distribute the RF input signal from an input of the distributed amplifier circuit to each respective amplification stage of the plurality of amplification stages; and
a double-sided DC feeding system configured to supply DC bias voltages to the plurality of amplification stages from a first end of the distributed amplifier circuit and a second end of the distributed amplifier circuit, thereby reducing current-resistance (iR) voltage drops in a DC bias line.

17. The distributed amplifier circuit of claim 16, wherein the double-sided DC feeding system comprises:
a first bias circuit to provide a first DC bias voltage to a first set of amplification stages of the plurality of amplification stages; and
a second bias circuit to provide a second DC bias voltage to a second set of amplification stages of the plurality of amplification stages, wherein the second DC bias voltage matches the first DC bias voltage.

18. The distributed amplifier circuit of claim 17, wherein the double-sided DC feeding system comprises:
first metallization to provide the first DC bias voltage to respective amplification stages of the first set of amplification stages from the first bias circuit of the plurality of amplification stages; and
second metallization to provide the second DC bias voltage to respective amplification stages of the second set of amplification stages from the second bias circuit of the plurality of amplification stages.

19. The distributed amplifier circuit of claim 18, wherein the double-sided DC feeding system comprises:
a damping resistor electrically coupling the first metallization and the second metallization, the damping resistor having a value selected to damp resonance voltages on the first metallization and the second metallization.

20. The distributed amplifier circuit of claim 19, wherein the damping resistor has a resistance value of approximately 50 Ohms to effectively suppress unwanted oscillations of voltage on the DC bias line.
